(19) United States
(12) Patent Application Publication
(10) Pub. No.: US 2008/0185709 A1
(43) Pub. Date: Aug. 7, 2008

(54) Semiconductor device including semiconductor elements and method of producing semiconductor device

(75) Inventors: Seiji Ishihara, Kashihara-shi (JP); Kezuo Tamaki, Kitakatsuragi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 12/068,159

(22) Filed: Feb. 4, 2008

(30) Foreign Application Priority Data
Feb. 5, 2007 (JP) 2007-26053

(51) Int. Cl. H01L 23/49; H01L 21/58

(52) U.S. Cl. 257/698; 438/107; 257/E23.024; 257/E21.505

(57) ABSTRACT

A semiconductor device including a plurality of semiconductor elements on a substrate, the semiconductor device includes: a plurality of semiconductor elements being provided two-dimensionally on a first surface of the substrate via an adhesive layer; and a hard member on surfaces of the plurality of semiconductor elements, the surfaces being on opposite sides with respect to other surfaces of the plurality of semiconductor elements which other surfaces face the first surface. This makes it possible to realize a thin semiconductor device that can prevent warping of the semiconductor device including a plurality of semiconductor elements.

This Nonprovisional application claims priority under 35 U.S.C. §119(a) on Patent Application No. 026053/2007 filed in Japan on Feb. 5, 2007, the entire contents of which are hereby incorporated by reference.

### FIELD OF THE INVENTION

The present invention relates to a multi-chip module semiconductor device (MCM semiconductor device) including a plurality of semiconductor chips (semiconductor elements) assembled in one IC package, more specifically, to a semiconductor device that is an MCM semiconductor device including a hard member that prevents deformation.

### BACKGROUND OF THE INVENTION

Packaging density of electronic components including an IC package is being increased, along with miniaturization and sophistication of performance of electronic apparatuses. A multi-chip module (MCM) semiconductor device is realized as effective means for increasing the packaging density. The MCM semiconductor device is an integrated circuit in which a plurality of semiconductor chips (semiconductor elements) are assembled in one IC package.

The MCM semiconductor device has a structure in which a plurality of semiconductor chips are provided side by side on one plane. Therefore, the MCM semiconductor device contributes to reduction of a mounting area, compared with a case where each semiconductor chip is mounted individually.

Moreover, it is a known technique to reduce a mounting area further by producing an MCM semiconductor device in which a plurality of semiconductor chips are stacked in an IC package.

For example, Japanese Unexamined Patent Publication No. 116566/2005 (Tokukai 2005-116566) (published on Apr. 28, 2005) (Publicly Known Document 1) discloses one example of an adhesive agent that is used when semiconductor chips are stacked and fixed. More specifically, Publicly Known Document 1 discloses a technique in which the adhesive agent is provided on a back surface of a semiconductor chip in advance. Then, when the semiconductor chip is stacked, the adhesive agent provided to a center section of the semiconductor chip is arranged to become thicker than the adhesive agent provided to a periphery section of the semiconductor chip. Moreover, in the technique, the adhesive agent has a flowable viscosity at a temperature at which the semiconductor chip is stacked. This technique prevents a residual void inside the adhesive agent or between the semiconductor chips bonded to each other.

However, the MCM semiconductor device has a structure in which a plurality of semiconductor chips are provided two-dimensionally or three-dimensionally. Therefore, a size of the MCM semiconductor device becomes larger than each of the individual semiconductor chips. This causes a problem that the MCM semiconductor device warps more easily due to heat generated during a production process or an operation of the MCM semiconductor device.

For example, in a production process of the MCM semiconductor device, a substrate constituting the MCM semiconductor device is sealed with resin after semiconductor chips are mounted on the substrate. Then, the resin is cured with heat at approximately 160° C. to 180° C. to form a sealing resin. In this production process, for example, the MCM semiconductor device may warp when the temperature of the semiconductor device heated to approximately 160° C. to 180° C. is cooled back to a room temperature.

This warping occurs because the substrate, the semiconductor chips, and the sealing resin have different thermal expansion coefficients, respectively. Specifically, the substrate has a thermal expansion coefficient from about 12 ppm/° C. to about 30 ppm/° C. and the semiconductor chips a thermal expansion coefficient from about 3 ppm/° C. to about 4 ppm/° C. Further, the sealing resin has a thermal expansion coefficient from about 8 ppm/° C. to about 20 ppm/° C. This causes a phenomenon similar to a so-called “bimetal effect”.

Such a phenomenon occurs due to heat load produced in the MCM semiconductor device. Accordingly, (i) during the production process of the MCM semiconductor device, (ii) when the MCM semiconductor device is mounted on a printed wiring board and subjected to a reflow process, or (iii) when the semiconductor chip mounted on the printed wiring board generates heat, or the like, the bimetal effect produces a stress to cause the MCM semiconductor device to warp. In a case where the MCM semiconductor device warps, a joint electrically connecting the MCM semiconductor device and a printed wiring board on which the MCM semiconductor device is mounted may be disconnected or the MCM semiconductor device itself may be destroyed due to the deformation. Therefore, techniques to prevent the warping of the MCM semiconductor device have been proposed.

For example, Japanese Unexamined Patent Publication No. 190547/2002 (Tokukai 2002-190547) (published on Jul. 5, 2002) (Publicly Known Document 2) discloses a technique for preventing a semiconductor device from warping. According to the technique, a substrate is arranged such that a thickness of a section on which a semiconductor chip is mounted is different from a thickness of a section on which no semiconductor chip is mounted. Specifically, the substrate has an increased thickness in the section on which the semiconductor chip is mounted, in order to suppress an angle at which the substrate is bent at edges of the semiconductor chip. On the other hand, the substrate has a reduced thickness in a section where no semiconductor chip is mounted. This prevents the substrate from stretching in the section on which no semiconductor chip is mounted. Publicly Known Document 2 discloses a technique for preventing the semiconductor device from warping by, as mentioned above, suppressing a difference between the thermal expansion of the semiconductor chip and the substrate on which the semiconductor chip is mounted.

Further, Japanese Unexamined Patent Publication No. 196008/2000 (Tokukai 2000-196008) (published on Jul. 14, 2000) (Publicly Known Document 3) discloses a technique in which, when semiconductor chips are mounted on a substrate, the semiconductor chips are arranged so that each of two center lines, that are formed by connecting middle points between substrate edges facing each other, has at least one semiconductor chip extending thereon. Moreover, any straight line, that passes between adjacent semiconductor chips and extends in parallel to the substrate, passes through one of the semiconductor chips mounted on the substrate.

As a result, according to the technique disclosed in Publicly Known Document 3, a section between semiconductor chips, in which section warping of a semiconductor device easily occurs, is strengthened by other semiconductor chip. This increases rigidity of the semiconductor device and consequently reduces warping of the semiconductor device.

However, the conventional arrangement cannot provide a thin semiconductor device that includes a plurality of semiconductor elements and also suppresses a warp.

The MCM semiconductor device is produced by assembling a plurality of semiconductor chips mounted two-dimensionally or three-dimensionally in one IC package. Moreover, the MCM semiconductor device is generally covered with a sealing resin so as to have a uniform thickness. That is, the sealing resin is formed to have a small thickness in a section where the semiconductor chip is mounted, whereas a large thickness in a section where no semiconductor chip is mounted.

In general, the thinner the MCM semiconductor device becomes, the larger the warping caused by heat load becomes. In a case where the MCM semiconductor device warps, electrode terminals for external connection of the MCM semiconductor device cannot be arranged side by side on one plane. This causes deterioration in coplanarity.

The deterioration in coplanarity causes difficulty in mounting the MCM semiconductor device on a printed wiring substrate or the like, difficulty in keeping sufficient reliability against heat load (temperature cycle) that occurs after mounting, or the like.

Moreover, a coplanarity specification value required by a user may not be satisfied.

Accordingly, reduction in warping of a package is a serious problem that needs to be solved for realization of a thin MCM semiconductor device.

FIG. 15(a) is a plan view of a conventional MCM semiconductor device. FIG. 15(b) is a cross sectional view taken along X-X′ of FIG. 15(a). As explained later, FIG. 15(c) is a cross sectional view illustrating a deformed state of the MCM semiconductor device illustrated in FIG. 15(b) which deformed state is caused by a warping stress produced in the MCM semiconductor device. FIG. 15(a) omits a sealing resin 580 for easier understanding of the drawing.

In a semiconductor device 500 as illustrated in FIG. 15(a), an adhesive layer 520 is provided on a substrate 510. Moreover, a plurality of semiconductor chips 530 (two semiconductor chips 530a and 530b in FIG. 15(a)) are provided further on the adhesive layer 520. In addition, a sealing resin 580 is formed so as to cover the substrate 510 and the semiconductor chips 530a and 530b.

The sealing resin 580 is formed to have a top surface having a uniform height from the substrate 510. Therefore, the sealing resin 580 has different thicknesses tA, tB, and tC. The thickness tA is a thickness in a section where the semiconductor chip 530a is provided. The thickness tB is a thickness in a section where the semiconductor chip 530b is provided. Moreover, the thickness tC is a thickness in a section where neither of the semiconductor chips 530a and 530b is provided.

The sealing resin is formed so that the thicknesses tA and tB of the sealing resin 580 in the sections where the plurality of semiconductor chips 530 are provided on the substrate 510 become smaller than the thickness tC where the plurality of semiconductor chips 530 are not provided.

Here, with reference to the MCM semiconductor device as illustrated in FIG. 15(a), explained is a warping stress produced in the MCM semiconductor device in a case where the sealing resin 580 is formed to have a small thickness.

As mentioned above, a thermal expansion coefficient of the sealing resin is larger than that of the semiconductor chip. Therefore, in a process in which the sealing resin 580 heated and melted is provided to form the sealing resin 580 on the substrate 510, where the plurality of semiconductor chips 530 are mounted, and then cooled down to a room temperature, the sealing resin 580 shrinks more significantly than the plurality of semiconductor chips 530.

Accordingly, as illustrated in FIG. 15(c), in a height direction of the substrate 510, the sealing resin 580 in a section having the thickness tC in which section the sealing resin 580 is formed to be thicker shrinks more significantly than the sealing resin 580 in sections having the thicknesses tA and tB. In other words, the sealing resin 580 between the semiconductor chips 530a and 530b shrinks to a large degree. This causes a warping stress in a direction in which the semiconductor chips 530a and 530b come closer to each other.

Next, explained is a case where the sealing resin 580 is formed to have smaller thicknesses of tA′, tB′, and tC′ in corresponding respective sections of the sealing resin 580 having the thicknesses tA, tB, and tC.

In this case, each thickness of the semiconductor chips 530a and 530b are unchanged. Therefore, the difference between the thicknesses tA′ and tC′ of the sealing resin does not change. Similarly, the difference between the thicknesses tB′ and tC′ of the sealing resin does not change. Therefore, the sealing resin 580 has a larger ratio of the thickness in the section where the plurality of semiconductor chips 530 are not provided with respect to each thickness in the sections where the plurality of semiconductor chips 530 are provided.

Accordingly, when the sealing resin 580 is formed to have a small thickness, a ratio at which the sealing resin 580 shrinks further increases in the section where the plurality of semiconductor chips 530 are not provided. This increases the warping stress in a direction in which the semiconductor chip 530a and 530b come closer to each other.

In other words, when the sealing resin 580 is formed to have a small thickness, the warping stress in the MCM semiconductor device increases. This may deteriorate coplanarity.

For example, in a case where a plurality of semiconductor chips are mounted on a substrate with a size of 6 mm×24 mm (aspect ratio: 4) and a thickness of 0.115 mm, an MCM semiconductor device in which a sealing resin is formed to have a thickness of 0.3 mm is easily warped by heat load in a production process or the like. Even in a case where the sealing resin is arranged to have a thickness of 0.4 mm, the MCM semiconductor device may warp.

Further, in a case where the sealing resin is arranged to have a thickness of 0.6 mm, warping of a small MCM semiconductor device is reduced. However, when the MCM semiconductor device employs a substrate with a large size (for example, 12 mm×12 mm) or a substrate with an aspect ratio greater than approximately 2, the MCM semiconductor device may warp.

In a case where the sealing resin is arranged to have a thickness equal to or more than 0.8 mm, the MCM semiconductor device becomes hard to warp because the MCM semiconductor device itself opposes the warping stress with the thickness thereof.

Further, when the substrate has a thickness of at least 0.15 mm, the MCM semiconductor device becomes hard to warp.

That is, the problem of the warping of the MCM semiconductor device is difficult to occur in a case where the MCM semiconductor device having a large thickness is produced. However, the problem of the warping occurs, when the sealing resin, the substrate, and the like are arranged to have small thicknesses so that a thin MCM semiconductor device is produced.

Accordingly, there is a demand for an MCM semiconductor device that does not warp even when the substrate and the sealing resin layer of the MCM semiconductor device are arranged to have small thicknesses.

Publicly Known Document 2 discloses a method in which the thickness of the substrate is arranged to be partially large in order to prevent the MCM semiconductor device from warping. Therefore, according to the method, it is not possible to further reduce the thickness of the MCM semiconductor device. Moreover, according to the method as described in Publicly Known Document 2, it is necessary to vary from part to part the thickness of the substrate in order to obtain a desirable thickness. This complicates the production process and causes cost increase.

Moreover, a method as disclosed in Publicly Known Document 3 is a technique that can prevent deformation of an MCM semiconductor device by using a rigidity of the semiconductor chip itself. However, according to the method, the arrangement can be realized with the use of at least three semiconductor chips. Accordingly, the method is not applicable to an MCM semiconductor device realized with the use of two semiconductor chips.

### SUMMARY OF THE INVENTION

The present invention is attained in view of the problems mentioned above. An object of the present invention is to realize a thin semiconductor device that is capable of preventing warping of the semiconductor device including a plurality of semiconductor elements and a production method of the semiconductor device.

In order to solve the problem mentioned above, the semiconductor device of the present invention including a plurality of semiconductor elements on a substrate, the semiconductor device includes: a plurality of semiconductor elements being provided two-dimensionally on a first surface of the substrate via an adhesive layer; and a hard member being provided via another adhesive layer on surfaces of the plurality of semiconductor elements provided on the first surface, the surfaces being on an opposite side with respect to other surfaces of the plurality semiconductor elements provided on the first surface which other surfaces facing the first surface.

According to the arrangement, the hard member is provided on the plurality of semiconductor elements. In other words, the hard member is provided so as to bridge the plurality of semiconductor elements provided in the semiconductor device of the present invention. Thus, the hard member functions as a support. Therefore, deformation of the semiconductor device of the present invention is hard to occur.

Moreover, as explained above, deformation of the semiconductor device is hard to occur. Accordingly, it becomes possible to reduce a thickness of a strengthening member used to prevent deformation of the semiconductor device. Therefore, it becomes possible to realize a thin semiconductor device that can suppress warping.

In order to solve the problem mentioned above, a semiconductor device of the present invention including a plurality of semiconductor elements on a substrate, the semiconductor device includes: a hard member provided on a first surface of the substrate via an adhesive layer; and a plurality of semiconductor elements provided two-dimensionally via another adhesive layer on a surface of the hard member which surface is on an opposite side to another surface of the hard member which another surface faces the first surface.

According to the arrangement, the hard member is provided on the substrate of the semiconductor device of the present invention via the adhesive layer, and the plurality of semiconductor elements are provided on the hard member via the another adhesive layer. In other words, the hard member is provided to strengthen the substrate. Therefore, deformation of the semiconductor device of the present invention is hard to occur.

Moreover, as explained above, deformation of the semiconductor device is hard to occur. Accordingly, it becomes possible to reduce a thickness of a strengthening member used to prevent deformation of the semiconductor device. Therefore, it becomes possible to realize a thin semiconductor device that can suppress warping.

In order to solve the problem mentioned above, a method of producing a semiconductor device including a plurality of semiconductor elements on a substrate includes steps of: forming an adhesive layer on a first surface of the substrate; providing a plurality of semiconductor elements on the adhesive layer; providing another adhesive layer on surfaces of the plurality of semiconductor elements which surfaces are on opposite sides to other surfaces of the plurality of semiconductor elements which other surfaces faces the first substrate; and providing a hard member on the another adhesive layer.

According to the arrangement, the semiconductor device is produced by sandwiching the plurality of semiconductor elements between the first surface of the substrate and the hard member.

The hard member is provided to bridge the plurality of semiconductor elements and provided between the plurality of semiconductor elements so as to function as a support. Therefore, deformation of the semiconductor device of the present invention becomes hard to occur. Moreover, as explained above, deformation of the semiconductor device is hard to occur. Accordingly, it becomes possible to reduce a thickness of a strengthening member used to prevent deformation of the semiconductor device. Therefore, it becomes possible to realize a thin semiconductor device that can suppress warping.

In order to solve the problem mentioned above, a method of producing a semiconductor device including a plurality of semiconductor elements on a substrate includes steps of: forming an adhesive layer on a first surface of the substrate; providing a hard member on the adhesive layer; providing another adhesive layer on a surface of the hard member which surface is on an opposite side to a surface of the hard member which surface faces the first substrate; and providing the plurality of semiconductor elements on the another adhesive layer.

According to the arrangement, the hard member is provided on the substrate of the semiconductor device of the present invention via the adhesive layer, and the plurality of semiconductor elements are further provided on the hard member via the another adhesive layer.

Therefore, because the hard member is provided so as to strengthen the substrate, deformation of the semiconductor device of the present invention is hard to occur. Moreover, as explained above, deformation of the semiconductor device is hard to occur. Accordingly, it becomes possible to reduce a thickness of a strengthening member used to prevent deformation of the semiconductor device. Therefore, it becomes possible to realize a thin semiconductor device that can suppress warping.

For a fuller understanding of the nature and advantages of the invention, reference should be made to the ensuing detailed description taken in conjunction with the accompanying drawings.

### BRIEF DESCRIPTION OF THE DRAWINGS

FIG. 1(a) is a plan view illustrating an exemplary embodiment of a semiconductor device of the present invention.

FIG. 1(b) is a cross sectional view taken along A-A′ of FIG. 1(a).

FIG. 2 is a cross sectional view illustrating a thickness of a layer of a sealing resin formed in the semiconductor device as illustrated in FIG. 1(b).

FIG. 3 is a cross sectional view illustrating another thickness of the layer of the sealing resin formed in the semiconductor device as illustrated in FIG. 1(b).

FIG. 4 is a cross sectional view illustrating another exemplary embodiment of the semiconductor device as illustrated in FIG. 1(a) and a structure in which semiconductor chips are mounted on a substrate by flip chip bonding.

FIG. 5 is a cross sectional view illustrating another exemplary embodiment of the semiconductor device as illustrated in FIG. 1(a) and a structure in which semiconductor chips are mounted on the substrate by wire bonding.

FIG. 6 is a cross sectional view illustrating another exemplary embodiment of the semiconductor device as illustrated in FIG. 1(a) and a structure in which a semiconductor chip is provided in lieu of a hard member.

FIG. 7 is a cross sectional view illustrating another exemplary embodiment of the semiconductor device as illustrated in FIG. 4 and a structure in which a sealing resin is not provided.

FIG. 8 is a cross sectional view illustrating another exemplary embodiment of the semiconductor device as illustrated in FIG. 1(a) and a structure in which a sealing resin is not provided on a part of a surface of a hard member.

FIG. 9 is a cross sectional view illustrating another exemplary embodiment of the semiconductor device as illustrated in FIG. 6 and a structure in which a sealing resin is not provided on a part of a surface of the semiconductor device provided on a top section.

FIG. 10 is a cross sectional view illustrating another exemplary embodiment of the semiconductor device as illustrated in FIG. 1(a) and a structure in which semiconductor chips are provided further on a hard member.

FIG. 11(a) is a plan view of another exemplary embodiment of a semiconductor device of the present invention.

FIG. 11(b) is a cross sectional view taken along B-B′ of FIG. 11(a).

FIG. 12 is a cross sectional view illustrating another exemplary embodiment of the semiconductor device as illustrated in FIG. 11(a) and a structure in which interconnection of semiconductor chips are carried out via through-hole electrodes provided to a hard member and the semiconductor chips.

FIG. 13 is a cross sectional view illustrating another exemplary embodiment of the semiconductor device as illustrated in FIG. 11(a) and a structure in which another hard member is provided further on the semiconductor chips.

FIG. 14(a) is a plan view illustrating a still another embodiment of a semiconductor device of the present invention.

FIG. 14(b) is a cross sectional view taken along C-C′ of FIG. 14(a).

FIG. 15(a) is a plan view illustrating an exemplary embodiment of a conventional semiconductor device.

FIG. 15(b) is a cross sectional view taken along X-X′ of FIG. 15(a).

FIG. 15(c) is a cross sectional view illustrating a state in which the semiconductor device in FIG. 15(b) warps.

### DESCRIPTION OF THE EMBODIMENTS

### First Embodiment

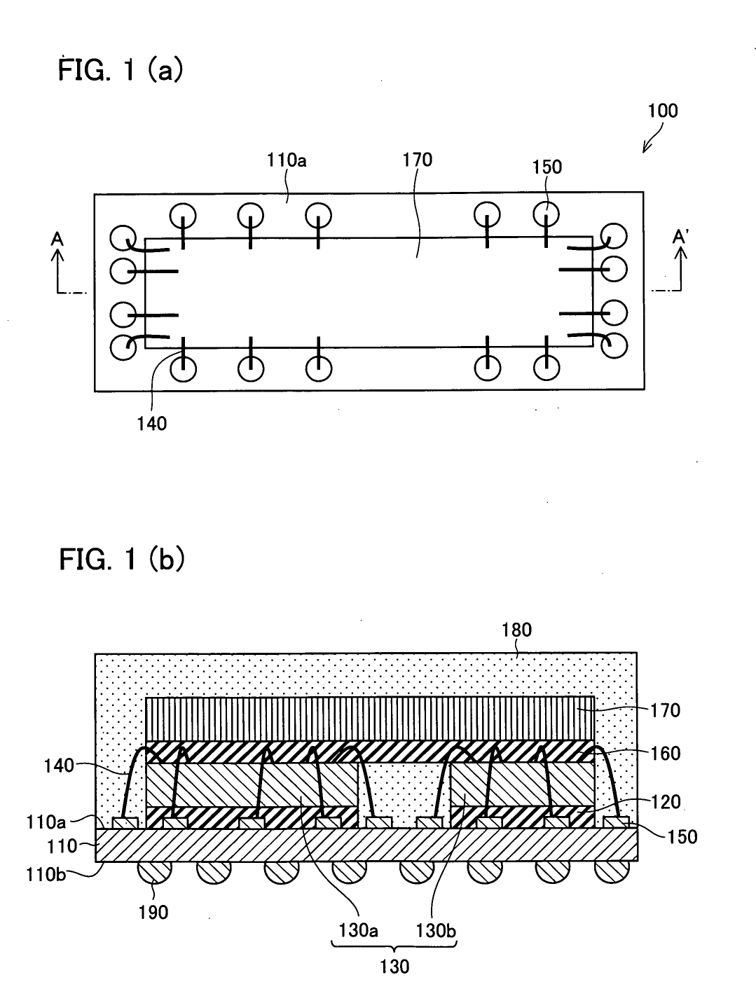

The following explains an embodiment of the present invention with reference to FIGS. 1(a) through 9.

FIG. 1(a) is a plan view illustrating a semiconductor device 100 of the present embodiment. FIG. 1(b) is a cross sectional view taken along A-A′ of FIG. 1(a). In FIG. 1(a), in order to assist understanding of the drawing, a sealing resin 180 is omitted. Hereinafter, an MCM semiconductor device is referred to simply as a semiconductor device.

The semiconductor device 100 of the present embodiment includes semiconductor chips 130 (semiconductor elements) provided on one plane on a first surface 110a of a substrate 110 via a first adhesive layer 120 (adhesive layer). The semiconductor device 100 of the present embodiment is provided with a plurality of semiconductor chips 130, thereby constituting a multi-chip module semiconductor device (MCM semiconductor device). In FIG. 1(a), two semiconductor chips, namely, semiconductor chips 130a and 130b are provided.

The substrate 110 may be a substrate including an insulating layer made of a resin polymer that is produced by curing of an organic material obtained by impregnating, with an organic material such as epoxy resin or BT (Bismaleimide Triazine), a base material made of, for example, a glass cloth, or the like. Moreover, the substrate 110 may be a substrate in which copper wiring is formed by patterning or the like on the insulating layer and insulation between the copper wirings is ensured by heat curing solder resist or the like that is further applied.

The first adhesive layer 120 may employ a known material for adhesion, such as die bonding paste, die attach film, or underfill.

The semiconductor chips 130a and 130b (semiconductor chips 130) are provided with pad sections (not shown). The pad sections are connected via fine metal wires 140 with electrode sections 150 (wiring electrodes) provided to the first surface 110a of the substrate 110, respectively. The pad sections are also electrically connected to the electrode sections 150, respectively. The fine metal wires 140 and the electrode sections 150 may be made of, for example, gold or aluminum.

On the other hand, a second surface 110b of the substrate 110 provided on a backside of the first surface 110a includes electrodes 190 for external connection (external connection electrodes) in the form of, for example, solder balls or the like via electrode sections as external connection terminals (not shown).

The electrode sections 150 formed on the first surface 110a of the substrate 110 are connected to the electrode sections as external connection terminals (not shown) formed on the second surface 110b by, for example, through holes or conductive pillars, and also electrically connected to each other.

In the semiconductor device 100 of the present embodiment, a second adhesive layer 160 (adhesive layer) is provided further on an upper side of (i) the semiconductor chips 130a and 130b and (ii) the fine metal wires 140 respectively provided to the semiconductor chips 130a and 130b and in a position opposed to the first surface 110a.

On the top of the second adhesive layer 160, a hard member 170 is further provided so as to bridge the semiconductor chips 130a and 130b. The semiconductor device 100 of the present embodiment has a sealing resin 180 (resin) that is provided to surround and seal the first surface 110a of the substrate 110, the first adhesive layer 120, the semiconductor chips 130, the fine metal wires 140, the electrode sections 150, the second adhesive layer 160, and the hard member 170. The sealing resin 180 may be a known sealing member such as epoxy resin.

The hard member 170 is provided as a support between the semiconductor chips 130a and 130b so as to bridge the semiconductor chips 130a and 130b. It is preferable that a total area of surfaces where the semiconductor chips 130a and 130b faces the hard member 170 is larger than an area of a surface where the hard member 170 faces the first surface 110a.

The semiconductor device 100 of the present embodiment includes the hard member 170 as mentioned above. Accordingly, it becomes possible to improve strength of the semiconductor device, compared with that of a semiconductor device including only a substrate, a sealing resin, and the like. This makes it possible to reduce a thickness of a member such as a substrate, a sealing resin, or the like, that improves the strength of the semiconductor device. Therefore, it becomes possible to realize a thin semiconductor device capable of preventing warping thereof.

It is preferable that the hard member 170 is made of a material with a thermal expansion coefficient that is one to two times a thermal expansion coefficient of the semiconductor chips 130a and 130b.

When the hard member 170 is made of a material with a thermal expansion coefficient that is more than twice the thermal expansion coefficient of the semiconductor chips 130, heat load extends or shrinks the hard member 170 more significantly than the semiconductor chips 130. This may produce a crack inside the semiconductor device 100 or destroy the semiconductor chips 130. Therefore, it is preferable that the thermal expansion coefficient of the hard member 170 is not more than twice the thermal expansion coefficient of the semiconductor chips 130.

For example, a thermal expansion coefficient of aluminum (thermal expansion coefficient: 23.5 ppm/° C.) or copper (thermal expansion coefficient: 17 ppm/° C.) is larger than two times a thermal expansion coefficient of a typical semiconductor chip (approximately 3 ppm/° C. to 4 ppm/° C.). Therefore, it is preferable that the hard member 170 is not made of these materials in the semiconductor device 100 of the present embodiment.

The hard member 170 can be made of, for example, silicon, or ceramics.

In a case where the thermal expansion coefficient of the semiconductor chips used in the semiconductor device of the present embodiment is larger than that of a typical semiconductor chip, a material of the hard member 170 may be determined according to the thermal expansion coefficient of the semiconductor chips. In such a case, aluminum or copper may become applicable to the material of the hard member.

The second adhesive layer 160 on which the hard member 170 is provided may employ a material as described in, for example, Publicly Known Document 1.

For example, the second adhesive layer 160 may employ an adhesive material that is solid at a room temperature but is in a melted state at a temperature at which the adhesive material comes into contact with a substance to be adhered such as the semiconductor chips 130. The second adhesive layer 160 may be made of an adhesive material whose viscosity (melt viscosity) at a temperature at which the adhesive material melts is not more than 50 Pa·s, and, more preferably, in a range from 3 Pa·s to 0.1 Pa·s.

If such an adhesive material is applied to a position where the second adhesive layer 160 is to be provided, the adhesive material is distributed, due to a surface tension of the adhesive material, such that the adhesive material becomes thick at a center section of the hard member 170 and thin at a periphery section of the hard member 170 in a case where the adhesive material provided between the hard member 170 and the semiconductor chips 130 is heated to melt. Accordingly, the second adhesive layer 160 becomes thick at the center section and thin at the periphery section.

As a result, the hard member 170 can be provided so as to cover the semiconductor chips 130a and 130b, and the fine metal wires 140 without deformation of the fine metal wires 140 or void formation. The second adhesive layer 160 may employ, for example, a liquid adhesive agent CRP-X4291 fabricated by Sumitomo Bakelite Co., Ltd.

Note that the second adhesive layer 160 is not limited to the liquid adhesive agent mentioned above, but may be any publicly known adhesive agent as long as the adhesive agent does not cause deformation of the fine metal wires 140 or void formation.

In other words, the semiconductor device 100 of the present embodiment can be fabricated by carrying out the following process.

First, the electrode sections 150 are formed on the first surface 110a of the substrate 110. Then, the electrode sections as external connection terminals (not shown) are formed on the second surface 110b on the backside of the first surface 110a. The electrode sections 150 and the electrode sections as external connection terminals are connected by interlayer connection via, for example, through holes or conductive pillars, and electrically connected to each other. The electrode sections as external connection terminals are provided with the electrodes 190 for external connection in the form of, for example, solder balls.

Next, the first adhesive layer 120 is formed on the first surface 110a of the substrate 110. The first adhesive layer 120 should be formed on the first surface 110a in positions where the plurality of semiconductor chips 130 (two semiconductor chips 130a and 130b in FIG. 1(a)) are provided.

Then, the semiconductor chips 130a and 130b are provided on the first adhesive layer 120.

Moreover, one ends of the fine metal wires 140 are connected to pad sections (not shown) provided on the semiconductor chips 130a and 130b, respectively. The other ends of the fine metal wires 140 are connected to the electrode sections 150 provided on the first surface 110a, respectively.

Then, the second adhesive layer 160 is formed on the semiconductor chips 130a and 130b. Further, the hard member 170 is provided so as to bridge the semiconductor chips 130a and 130b. Subsequently, the sealing resin 180 is provided so as to surround and seal the first surface 110a of the substrate 110, the first adhesive layer 120, the semiconductor chips 130, the fine metal wires 140, the electrode sections 150, the second adhesive layer 160, and the hard member 170.

Next, the following explains an effect of preventing warping which effect is realized by the semiconductor device 100 of the present embodiment.

Different from a conventional semiconductor device, the semiconductor device 100 of the present embodiment is provided with the second adhesive layer 160 and the hard member 170. Accordingly, in a case where the sealing resin 180 is formed to the same height from the substrate 110 as that of the conventional semiconductor device, the thickness of the sealing resin 180 is reduced by a thickness of the second adhesive layer 160 and a thickness of the hard member 170.

The section where the thickness of the sealing resin 180 is reduced is provided with the hard member 170 made of a material whose thermal expansion coefficient is one to two times the thermal expansion coefficient of the semiconductor chips 130.

A typical thermal expansion coefficient of the sealing resin 180 is in a range from about 8 ppm/° C. to about 20 ppm/° C. and a typical thermal expansion coefficient of the semiconductor chips 130 is in a range from about 3 ppm/° C. to about 4 ppm/° C. Accordingly, it is preferable that the thermal expansion coefficient of the hard member 170 formed as mentioned above is, for example, in a range from about 3 ppm/° C. to about 8 ppm/° C.

In the semiconductor device 100 of the present embodiment, as mentioned above, a part of the sealing resin 180 is replaced with the second adhesive layer 160 and the hard member 170. The part of the sealing resin 180 replaced is replaced mainly by the hard member 170, in regard to the thickness.

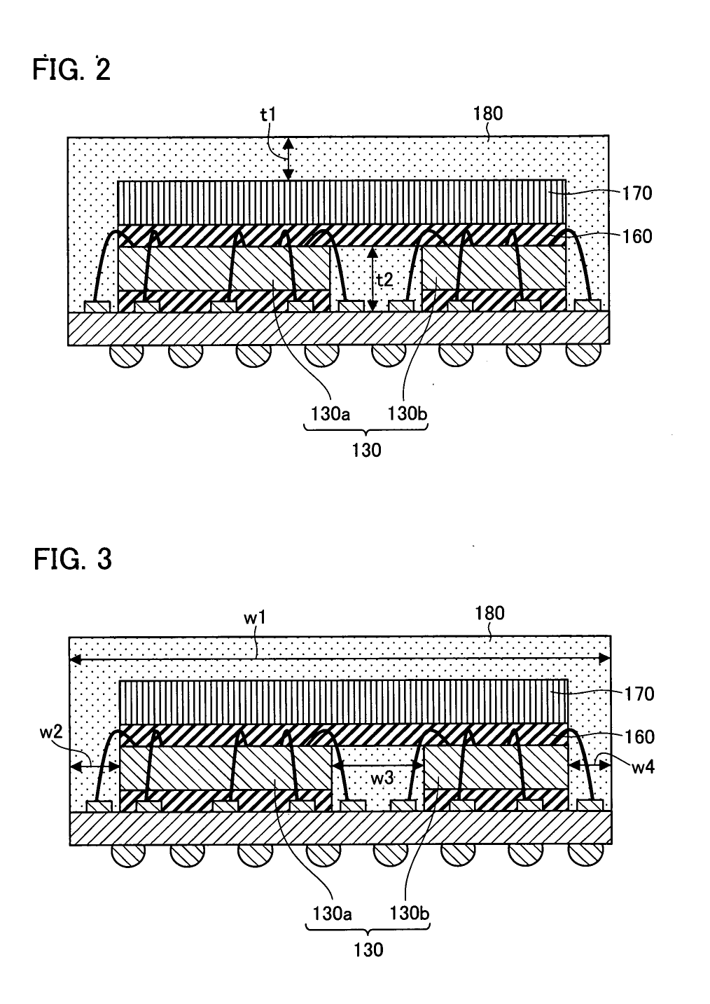

A thermal expansion coefficient of the hard member 170 is smaller than that of the sealing resin 180 and one to two times a thermal expansion coefficient of the semiconductor chips 130. Accordingly, it becomes possible to reduce, by using the second adhesive layer 160 and the hard member 170, the influence to top sections of the semiconductor chips 130 from extension or shrinkage due to heat (which top sections are on a side provided with the first surface 110a of the substrate 110 and face a direction away from the first surface 110a). FIG. 2 is a cross sectional view illustrating a thickness of a layer of the sealing resin 180 formed in the semiconductor device 100 of the present embodiment.

As illustrated in FIG. 2, the sealing resin 180 is formed so as to have a thickness of t1 above the hard member 170 and a thickness of t2 below the second adhesive layer 160. Meanwhile, the sealing resin 180 is formed to have a thickness of t3 at a part where the semiconductor chip 130a or the like is not provided.

In the semiconductor device 100 of the present embodiment, as illustrated in FIG. 2, the hard member 170 is provided so as to bridge the semiconductor chips 130a and 130b.

Therefore, the sealing resin 180 provided between the semiconductor chips 130a and 130b has thicknesses of t2 and t1 in this order from the first surface 110a of the substrate 110.

The thickness of the sealing resin 180 is t1 above the hard member 170. Accordingly, when the layer of the sealing resin 180 having the thickness of t1 extends or shrinks due to heat load, the thickness of t1 of the sealing resin 180 above the hard member 170 uniformly extends or shrinks in respective regions above the semiconductor chips 130a and 130b and above a space between the semiconductor chips 130a and 130b. In other words, the semiconductor device of the present embodiment is difficult to warp due to extension or shrinkage of the sealing resin 180 formed above the hard member 170.

Therefore, in the semiconductor device 100 of the present embodiment, in regard to a stress to warp the semiconductor device 100 (warping stress) between the semiconductor chips 130a and 130b, a warping stress should be examined only in the section where the sealing resin 180 has a thickness of t2.

Next, explained is a case where the sealing resin 180 having a thickness of t2 provided between the hard member 170 and the substrate 110 extends or shrinks due to heat load. In this case, a stress occurs on each boundary of regions including (a) the first adhesive layer 120 and the semiconductor chip 130a, (b) the first adhesive layer 120 and the semiconductor chip 130b, and (c) the sealing resin 180, due to difference in extension or shrinkage (i) between (a) and (c) and (ii) between (b) and (c). Due to the difference in a degree of each stress, the warping stress to warp the semiconductor device 100 is applied to layers made of the substrate 110, the hard member 170, and the second adhesive layer 160.

The semiconductor device 100 of the present embodiment is supported against this warping stress by the substrate 110, the hard member 170, and the second adhesive layer 160.

In other words, the semiconductor device 100 of the present embodiment is supported against the warping stress caused by the sealing resin 180 in the section where the sealing resin 180 has the thickness of t2, with the use of the substrate 110, the hard member 170, and the second adhesive layer 160 that are strengthening members provided above and below the semiconductor chips 130. Therefore, the semiconductor device 100 can be prevented from warping.

Moreover, the substrate 110, the hard member 170, and the second adhesive layer 160 which are strengthening members of the semiconductor device 100 are effective in preventing deformation of the semiconductor device 100 due to the stress, caused by the extension or shrinkage of the sealing resin 180, that works in a direction parallel to the substrate 110.

FIG. 3 is a cross sectional view illustrating a thickness of a layer of the sealing resin 180 formed in the semiconductor device 100 of the present embodiment as illustrated in FIG. 1(b). FIG. 3 is different from FIG. 2 in that the thickness of the layer of the sealing resin 180 is defined in a different direction. Namely, FIG. 3 illustrates a thickness of the layer of the sealing resin 180 in a direction parallel to the substrate 110.

As illustrated in FIG. 3, w1 is a layer thickness of the sealing resin 180 in a direction parallel to the substrate 110 above the hard member 170. w2 is a layer thickness of the sealing resin 180 provided from an edge section of the sealing resin 180 to the semiconductor chip 130a, w3 a layer thickness of the sealing resin 180 provided between the semiconductor chips 130a and 130b, and w4 a layer thickness of the sealing resin 180 provided from the semiconductor device 130b to another edge section of the sealing resin 180, in a region from the substrate 110 to the height at which the second adhesive layer 160 is provided. The semiconductor device 100 of the present embodiment is supported against a warping stress caused by the extension or shrinkage of the sealing resin 180 having a thickness of w1, by the substrate 110, the hard member 170, and the second adhesive layer 160. In semiconductor device 100 of the present embodiment, the hard member 170 and the second adhesive layer 160 are additionally provided to an arrangement of a conventional semiconductor device. Therefore, a region where the sealing resin 180 is formed is smaller than that in the arrangement of the conventional semiconductor device. Therefore, the stress caused by the extension or shrinkage in the section of the sealing resin 180 having the thickness w1 becomes smaller than that in the conventional semiconductor device.

Moreover, the semiconductor device 100 of the present embodiment is supported against the stress that occurs in the sections of the sealing resin 180 having the thicknesses w2, w3, and w4, by the substrate 110, the hard member 170, and the second adhesive layer 160 that are the strengthening members. Different from a conventional semiconductor device, the hard member 170 and the second adhesive layer 160 function as a support and support the semiconductor device 100 so that the positions of the semiconductor chips 130a and 130b are not drawn away from each other. Therefore, the hard member 170 and the second adhesive member 160 are effective in preventing deformation of the semiconductor device 110 caused by the extension or shrinkage of the sealing resin 180 particularly in the section where the sealing resin 180 has the thickness w3.

Further, in the semiconductor device 100 of the present embodiment, the thermal expansion coefficient of the hard member 170 is smaller than that of the substrate 110. Therefore, the hard member 170 is also effective in preventing extension or shrinkage in a direction parallel to the substrate 110.

As mentioned above, in the semiconductor device 100 of the present embodiment, the hard member 170 is provided to the semiconductor chips 130a and 130b via the second adhesive layer 160. The hard member 170 is made of a material having a thermal expansion coefficient of one to two times the thermal expansion coefficient of the semiconductor chips 130. The hard member 170 and the second adhesive layer 160 function as a support and support the semiconductor device 100 so that the positions of the semiconductor chips 130a and 130b are not drawn away from each other. Therefore, the hard member 170 is effective in preventing warping or deformation caused by the extension or shrinkage of the substrate 110.

In the semiconductor device 100 of the present embodiment, it is preferable that an area of the surface of the hard member 170 which surface faces the first surface 110a is larger than a total area of the surfaces of the semiconductor chips 130a and 130b which surfaces face the hard member 170.

In this way, warping or deformation of the semiconductor device 100 of the present embodiment is hard to occur. Therefore, reliability of the operation of the semiconductor device 100 can be maintained against a sufficient number of times of temperature cycles.

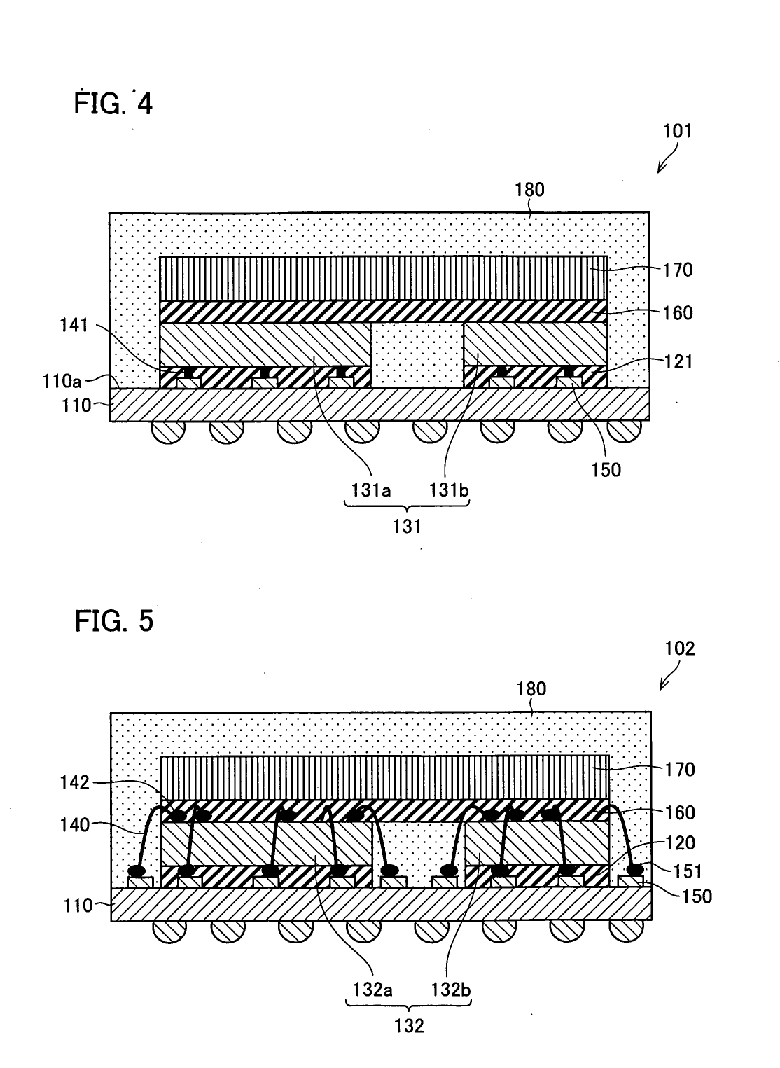

The semiconductor device 100 of the present embodiment has a structure as mentioned above. Alternatively, the semiconductor device 100 of the present embodiment may have an arrangement in which, as in the semiconductor device 101 as illustrated in FIG. 4, for example, a plurality of semiconductor chips 131 (two semiconductor chips 131a and 131b of FIG. 4) mounted on the semiconductor device 101 have bump electrodes 141 and the electrode sections 150 provided to the first surface 110a of the substrate 110 is connected with the bump electrodes 141 by flip chip bonding, respectively. The flip chip bonding may be carried out by, for example, a known method such as a method of jointing gold bumps to the electrode sections 150 with heat or a method using an anisotropic conductive film.

Particularly in the case of the method using an anisotropic conductive film, the semiconductor device 101 may be provided with an anisotropic conductive film 121 in a position where the first adhesive layer 120 is provided in the semiconductor device 100.

Note that the semiconductor device 101 may have an arrangement such that, in a region where the semiconductor chips 131a and 131b and the first surface 110a face each other, the anisotropic conductive film 121 is provided to contact sections where the bump electrodes 141 and the electrode sections 150 are respectively in contact with each other and, in the region other than the contact sections, the first adhesive layer 120 is provided.

Alternatively, as in a semiconductor device 102 as illustrated in FIG. 5, semiconductor chips 132 (two semiconductor chips 132a and 132b in FIG. 5) may have upper bump electrodes 132, and the electrode sections 150 provided to the first surface 110a of the substrate 110 may be further provided with crimp balls 151 (crimp bump electrodes). In the arrangement, the upper bump electrodes 142 and the crimp balls 151 may be connected via the fine metal wires 140, in other words, be electrically connected in a reverse wire bonding process.

Warping and deformation of thus arranged semiconductor devices 101 and 102 of the present embodiment are hard to occur. Therefore, reliability of the operation of the semiconductor devices 101 and 102 can be maintained against a sufficient number of times of temperature cycles.

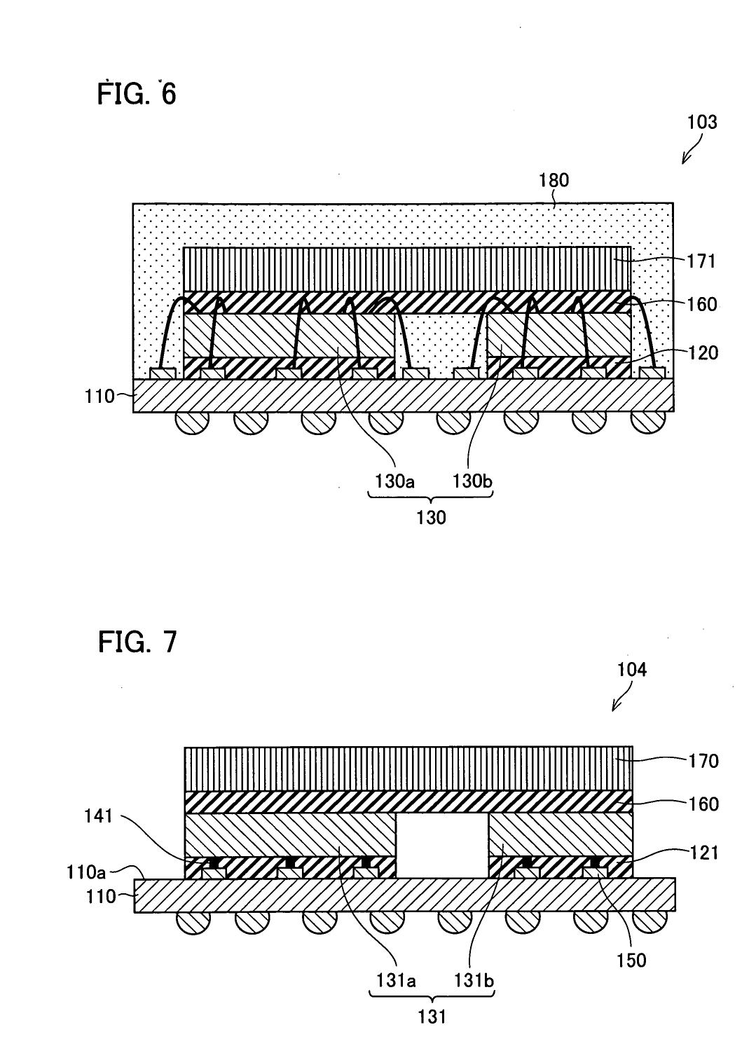

Moreover, as illustrated in FIG. 6, a semiconductor chip 171 (semiconductor element) may be provided in lieu of the hard member 170. In a semiconductor device 103 as illustrated in FIG. 6, the hard member 170 of the semiconductor device 100 is replaced with the semiconductor chip 171.

The semiconductor chip 171 is provided to bridge the semiconductor chips 130a and 130b in the same way as the hard member 170. Namely, the semiconductor chip 171 is provided as a support between the semiconductor chips 131a and 131b. It is preferable that an area of a surface of the semiconductor chip 171 which surface faces the first surface 110a is larger than the total area of the surfaces of the semiconductor chips 130a and 130b which surface face the semiconductor chip 171.

With the arrangement in which the semiconductor chip 171 is provided in lieu of the hard member 170, the semiconductor chips can be mounted at a high density. Moreover, it becomes possible to realize a semiconductor device whose deformation such as warping is hard to occur. Therefore, reliability of the operation of the semiconductor device 103 can be maintained against a sufficient number of times of temperature cycles.

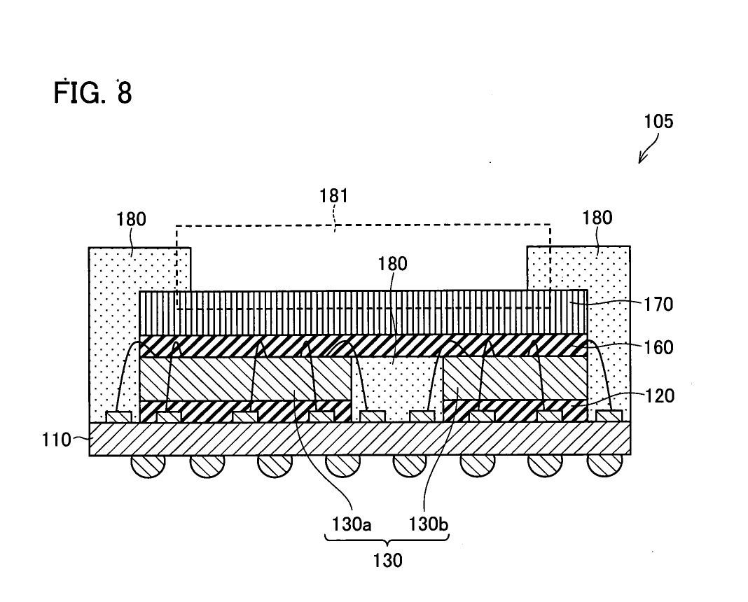

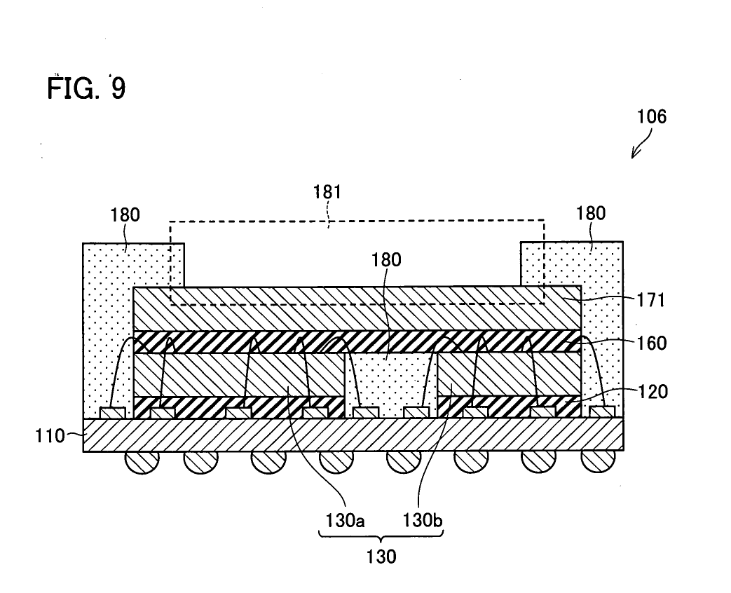

Further, as illustrated in FIG. 7, it is possible to have an arrangement in which the sealing resin 180 is not provided. Further, as illustrated in FIGS. 8 and 9, the hard member 170 or the semiconductor chip 171 may be arranged to be partially exposed from the sealing resin 180.

A semiconductor device 104 as illustrated in FIG. 7 shows an arrangement in which the sealing resin 180 is not provided in the arrangement of the semiconductor device 101.

A semiconductor device 105 as illustrated in FIG. 8 shows an arrangement in which the sealing resin 180 is not provided to a part of a surface that belongs to the hard member 170 facing the first surface 110a and is provided on a further side from the first surface 110a in the arrangement of the semiconductor device 101. Further, a semiconductor device 106 as illustrated in FIG. 9 shows an arrangement in which the sealing resin 180 is not provided to an opening section 181 that is formed on a part of a surface that belongs to the semiconductor chip 171 facing the first surface 110a and provided on a further side from the first surface 110a in the arrangement of the semiconductor device 103.

If a sealing resin is not provided in an arrangement of a conventional semiconductor device as in the semiconductor devices 104 through 106 of the present embodiment, a shape of the conventional semiconductor device is supported only by the substrate. However, in a case where a thin semiconductor device is produced, the substrate needs to be thinned down. Accordingly, in a case where a thin semiconductor device is produced, the substrate becomes thin and rigidity to keep the shape of the semiconductor device becomes low. Such a semiconductor device may be bent with a small external force.

Each of the semiconductor devices 104 through 106 of the present embodiment is provided with the hard member 170 or the semiconductor chip 171. The hard member 170 or the semiconductor chip 171 is provided as a support that bridges between the semiconductor chips 130 or the like in the semiconductor devices 104 through 106. Therefore, it is possible to increase rigidity of the semiconductor devices 104 through 106.

Because each of the semiconductor devices 104 through 106 has the opening section 181 where the sealing resin 180 is not provided, the semiconductor device is hard to warp due to a difference between the thermal expansion coefficient of the sealing resin 180 and the thermal expansion coefficient of the semiconductor chips 130, or the like.

Further, because the sealing resin 180 is not provided, heat dissipation of the semiconductor devices 104 through 106 is improved.

In particular, the semiconductor device 106 has an arrangement in which a part of the surface of the semiconductor chip 171 is exposed outside from the opening section 181. Accordingly, the semiconductor chip 171 may be a light-receiving element such as CCD (Charge Coupled Device) or a CMOS image sensor (CMOS: Complementary Metal Oxide Semiconductor), a sensor chip, or the like. Moreover, the semiconductor chip 171 may be a light-emitting device such as an LED (Light Emitting Diode) or the like.

In the semiconductor devices 104 through 106, an area of the surface of the hard member 170 which surface faces the first surface 110a is larger than a total area of the surfaces of the semiconductor chips 130a and 130b or the semiconductor chips 131a and 131b which surfaces face the hard member 170. This provides multiple effects of improving heat dissipation and stabilizing an electric characteristic or optical characteristic of the semiconductor device.

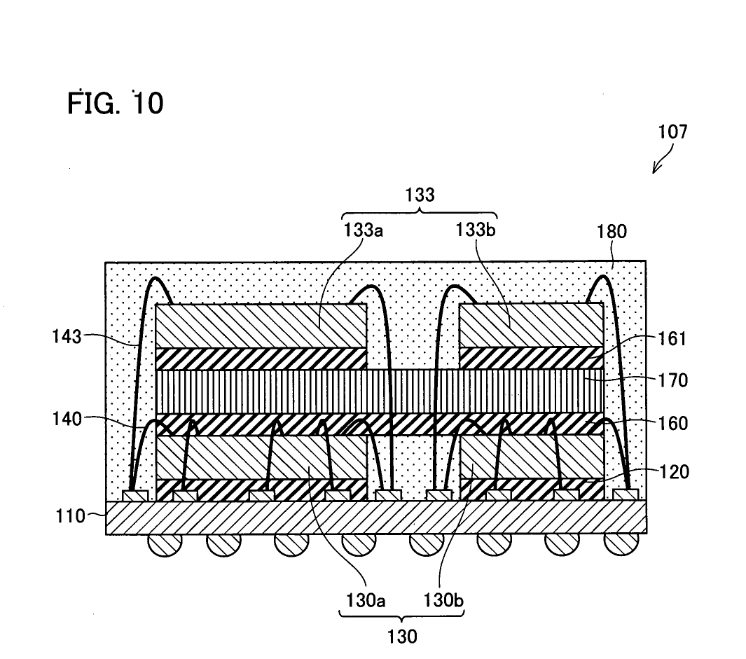

As illustrated in the semiconductor device 107 as illustrated in FIG. 10, the semiconductor device 100 may have an arrangement in which, after a third adhesive layer 161 (adhesive layer) is provided further on the hard member 170 and a plurality of semiconductor chips 133 (semiconductor elements) are provided further on the third adhesive layer 161, the sealing resin 180 is provided so as to surround and seal the plurality of the semiconductor chips 133, the third adhesive member 161, and the like.

In FIG. 10, the two semiconductor chips 133a and 133b are provided as the plurality of the semiconductor chips 133. The semiconductor chips 133 (semiconductor chips 133a and 133b) are provided with pad sections (not shown). The pad sections are connected to the electrode sections 150 via second fine metal wires 143. The pad sections and the electrode sections 150 are thus electrically connected. The second fine metal wire 143 may be made of, for example, gold or aluminum.

As mentioned above, in the semiconductor device 107, because a plurality of semiconductor chips are combined three-dementionally, the plurality of semiconductor chips can be mounted at a high density. Moreover, it becomes possible to realize a semiconductor device whose deformation such as warping is hard to occur. Therefore, reliability of the operation of the semiconductor device 107 can be maintained against a sufficient number of times of temperature cycles.

Note that more semiconductor chips and hard members may be stacked to form additional upper layers with a combination of the methods of stacking the layers, although the explanation above dealt with an arrangement in which the semiconductor chips and the hard members are stacked to form up to three layers.

### Second Embodiment

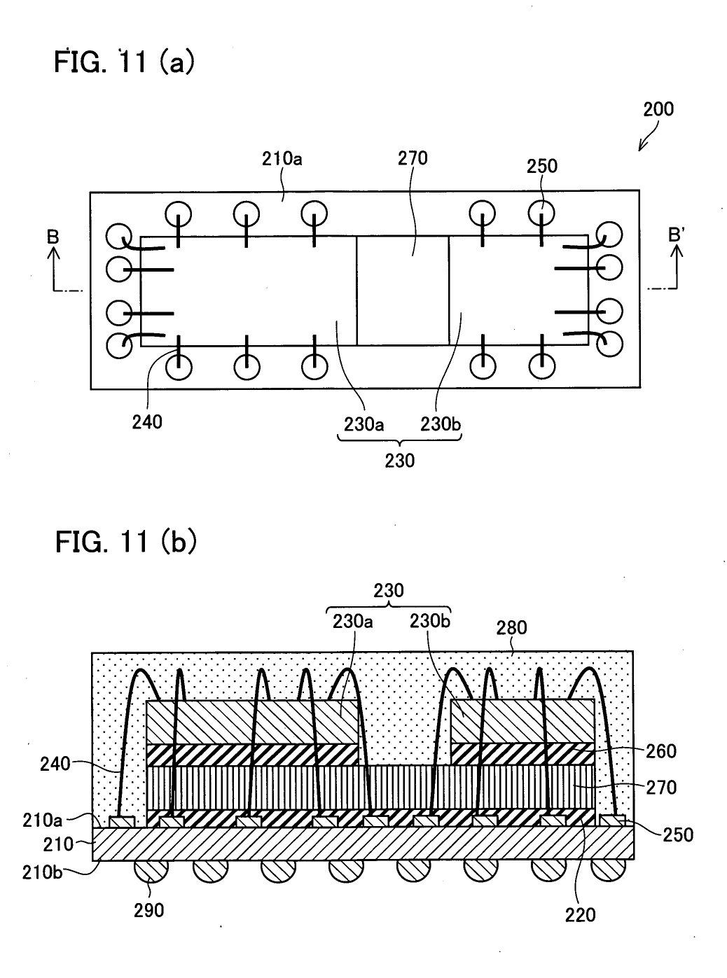

With reference to FIGS. 11(a) through 13, the following explains another embodiment of the present invention. The arrangement other than explained below is the same as the arrangement of the first embodiment. For convenience of explanation, members given the same reference numerals as the members explained in the first embodiment respectively have identical functions and the explanations thereof are omitted.

FIG. 11(a) is a plan view illustrating a semiconductor device 200 of the present embodiment. FIG. 11(b) is a cross sectional view taken along B-B′ of FIG. 11(a). In FIG. 11(a), a sealing resin 280 is omitted for helping the understanding of the drawing.

The semiconductor device 200 of the present embodiment is provided with a hard member 270 on a first surface 210a of a substrate 210 via a first adhesive layer 220. The substrate 210 is made of a similar material as a material of a substrate 110. The first adhesive layer 220 is made of a similar material as a material of a first adhesive layer 120. Moreover, the hard member 270 is made of a similar material as a material of a hard member 170.

In the explanation of the semiconductor device 200, an adhesive member provided between a first surface 210a and the hard member 270 is the first adhesive layer 220. However, the adhesive member may be made of a similar material as a material of a second adhesive layer 160 described in the first embodiment.

In the semiconductor device 200 of the present embodiment, a second adhesive layer 260 is provided on the hard member 270 and a plurality of semiconductor chips 230 are provided on one plane further on the second adhesive layer 260. In FIG. 11(a), two semiconductor chips provided are semiconductor chips 230a and 230b.

Similar to the first adhesive layer 220, the second adhesive layer 260 is made of a similar material to the material of the first adhesive layer 120 or the second adhesive layer 160 described in the first embodiment. Moreover, the semiconductor chips 230a, 230b, and the like are made of materials similar to materials of semiconductor chips 130a, 130b, and the like, respectively.

The semiconductor chips 230a and 230b (semiconductor chips 230) are provided with pad sections (not shown). The pad sections are respectively connected with fine metal wires 240 to electrode sections 250 provided to the first surface 210a of the substrate 210. The pad sections and the electrode sections 250 are also connected electrically. The fine metal wires 240 are made of a similar material to a material of fine metal wires 140. Moreover, the electrode sections 250 are made of a similar material to a material of electrode sections 150.

On the other hand, the second surface 210b on a backside of the first surface 210a of the substrate 210 is provided with external connection electrodes 290 via electrode sections as external connection terminals (not shown). The external connection electrodes 290 are made of a similar material as a material of external connection electrodes 190.

The electrode sections 250 formed on the first surface 210a of the substrate 210 are connected to the electrode sections as external connection terminals formed on the second surface 210b of the substrate 210, by interlayer connection with, for example, through holes or conductive pillars. The electrode sections 250 are thus electrically connected to the electrode sections as external connection terminals.

The semiconductor device 200 of the present embodiment are provided with sealing resin 280 so as to surround and seal the first surface 210a of the substrate 210, the first adhesive layer 220, the hard member 270, the second adhesive layer 260, the semiconductor chips 230, the fine metal wires 240, and the electrode sections 250. The sealing resin 280 is made of a sealing material similar to a material of a sealing resin 180 or the like.

The hard member 270 is provided between the semiconductor chips 230a and 230b and the substrate 210. It is preferable that an area of the hard member 270 which surface faces the first surface 210a is larger than a total area of surfaces of the semiconductor chips 230a and 230b which surfaces face the hard member 270.

Moreover, it is preferable that the hard member 270 is made of a material that has a thermal expansion coefficient of one to two times thermal expansion coefficients of the semiconductor chips 230a and 230b.

In this arrangement, the hard member 270 supports the substrate 210 and the semiconductor chips 230 against a warping stress operating in the substrate 210 and the semiconductor chips 230. Therefore, deformation, such as warping, of the semiconductor device 200 of the present embodiment is difficult to occur.

Moreover, a typical substrate has a thermal expansion coefficient of about 12 ppm/° C. to about 30 ppm/° C. It is well known that the thermal expansion coefficient is larger than a thermal expansion coefficient of about 3 ppm/° C. to about 4 ppm/° C. of a typical semiconductor chip.

In the arrangement of the semiconductor device 200 of the present embodiment, the hard member 270 has a value of one to two times the thermal expansion coefficient of the semiconductor chips 230. The hard member 270 is provided between the semiconductor chips 230 and the substrate 210. Therefore, in a case where heat load is applied to the semiconductor device 200 of the present embodiment, the semiconductor chips 230 are not directly influenced by extension or shrinkage of the substrate 210. The semiconductor chips 230 is influenced by extension or shrinkage of the hard member 270, which extension or shrinkage occurs as a result of extension or shrinkage of the substrate 210 and the hard member 270 due to heat.

At this time, compared with a case where heat load is applied to the hard member 270 independently, the hard member 270 extends or shrinks more significantly. This is because the hard member 270 is jointed to the substrate 210 via the first adhesive layer 220. However, the extension or shrinkage of the hard member 270 is smaller than the extension or shrinkage of the substrate 210. Therefore, the influence of the warping stress on the semiconductor chips 230 from the extension or shrinkage of the substrate 210 is reduced by providing the hard member 270.

In other words, warping and deformation of the semiconductor device 200 of the present embodiment is hard to occur when heat load is applied. Therefore, reliability of the operation of the semiconductor device 200 can be maintained against a sufficient number of times of temperature cycles.

Moreover, compared with the strength of the semiconductor device with only a substrate, a sealing resin, and the like, the strength of the semiconductor device 200 of the present embodiment can be improved because the semiconductor device 200 includes the hard member 270 above. This makes it possible to reduce a thickness of a member whose strength is supported by a substrate, a sealing resin, and the like. Therefore, it becomes possible to produce a thin semiconductor device that prevents warping.

The semiconductor device 200 as explained above can be produced in the following process.

First, the electrode sections 250 are formed on the first surface 210a of the substrate 210. Then, electrode sections as external connection terminals (not shown) are formed on the second surface 210b on the backside of the first surface 210a of the substrate 210. The electrode sections 250 and the electrode sections as external connection terminals are connected by interlayer connection with, for example, through holes or conductive pillars, and connected electrically. Further, the electrode sections as external connection terminals are provided with the external connection electrodes 290 made of, for example, solder balls.

Next, the first adhesive layer 220 is formed on the first surface 210a of the substrate 210. The first adhesive layer 220 is formed in accordance with the position of the hard member 270 to be provided on the first adhesive layer 220.

Then, the hard member 270 is provided on the first adhesive layer 220.

Next, the second adhesive layer 260 is formed on the hard member 270. Then, the semiconductor chips 230a and 230b are provided further on the second adhesive layer 260.

Further, one ends of the fine metal wires 240 are respectively connected to the pad sections (not shown) provided to the semiconductor chips 230a and 230b. The other ends of the fine metal wires 240 are connected to the electrode sections 250 provided to the first surface 210a.

Then, the sealing resin 280 is provided so as to surround and seal the first surface 210a of the substrate 210, the first adhesive layer 220, the hard member 270, the second adhesive layer 260, the semiconductor chips 230, the fine metal wires 240, and the electrode sections 250.

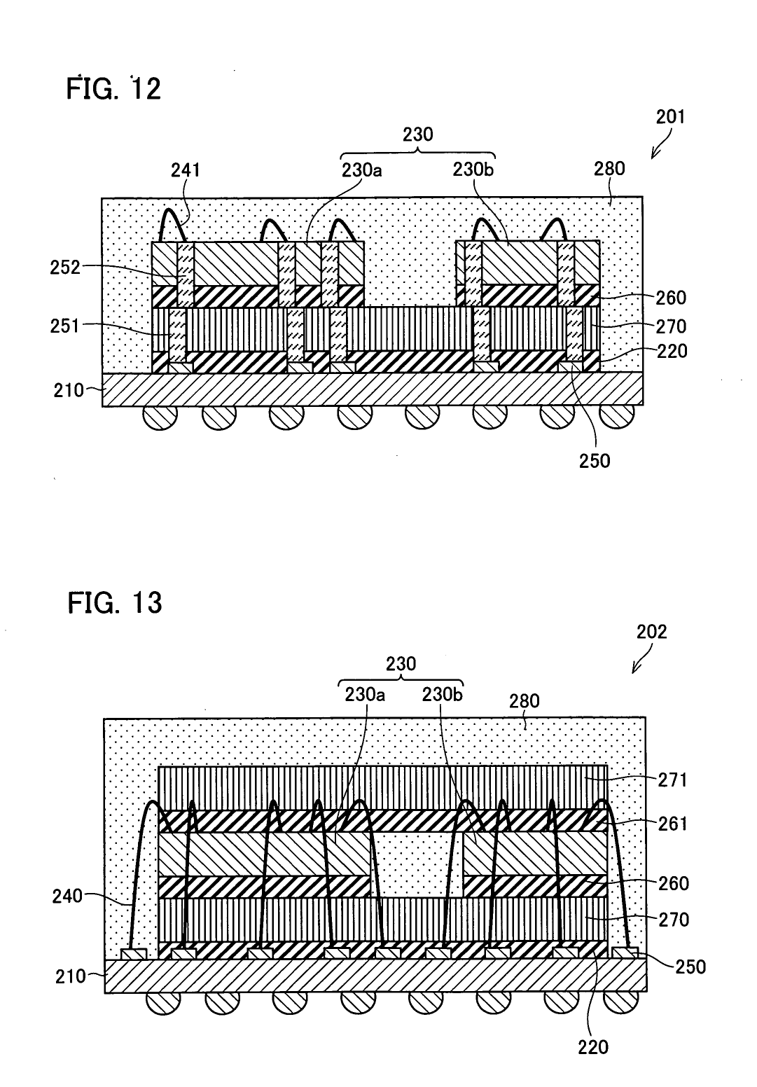

The above explanation describes that, in the semiconductor device 200 of the present embodiment, the electrode sections 250 provided to the substrate 210 and the semiconductor chips 230 are connected with the fine metal wires 240. However, note that a method of connecting the electrode sections 250 and the semiconductor chips 230 is not limited to the method explained above. The electrode sections 250 and the semiconductor chips 230 may be connected, for example, by flip chip bonding or reverse wire bonding as explained in the first embodiment. Further, as in the semiconductor device 201 as illustrated in FIG. 12, the pad sections (not shown) provided to the semiconductor chips 230 and the electrode sections 250 may be electrically connected via first through-hole electrodes 251 and second through-hole electrodes 252 which are provided to the hard member 270 and the semiconductor chips 230.

In the semiconductor device 201 of the present embodiment, the first through-hole electrodes 251 are provided between two surfaces (upper surface and lower surface) of the hard member 270, and the second through-hole electrodes 252 are provided between two surfaces (upper surfaces and lower surfaces) of the semiconductor chips 230. The pad sections (not shown) provided to the semiconductor chips 230 are connected to the second through-hole electrodes 252 via third fine metal wires 243. Moreover, the second through-hole electrodes 252 are electrically connected to the first through-hole electrodes 251. Further, the first through-hole electrodes 251 are electrically connected to the electrode sections 250. As a result, warping and deformation of the semiconductor device 201 of the present embodiment becomes hard to occur when heat load is applied. Therefore, reliability of the operation of the semiconductor device 201 can be maintained against a sufficient number of times of temperature cycles.

Moreover, as in the semiconductor device 202 as illustrated in FIG. 13, the semiconductor device 200 may have an arrangement in which, after a third adhesive layer 261 is further provided on the semiconductor chips 230 of the semiconductor device 200 and a second hard member 271 is further provided on the third adhesive layer 261, the sealing resin 280 is provided to surround and seal the second hard member 271 and the like.

In the semiconductor device 202, the third adhesive layer 261 is provided in a position that is on the semiconductor chips 230a and 230b and the fine metal wires 240 and faces the first surface 210a. It is preferable that the third adhesive layer 261 is made of a similar material to the material of the second adhesive layer 160 as described in the first embodiment.

Because, as described above, the hard member 270 and the second hard member 271 are provided above and below the semiconductor chips 230a and 230b in the semiconductor device 202, it becomes possible to obtain a semiconductor device that has an improved rigidity. This makes it possible to realize a semiconductor device whose deformation such as warping is hard to occur, even in a case where heat load is applied by a sufficient number of times of temperature cycles.

In addition, the sealing resin 280 of these semiconductor devices may be partially or entirely removed as illustrated in FIGS. 7 through 9.

### Third Embodiment

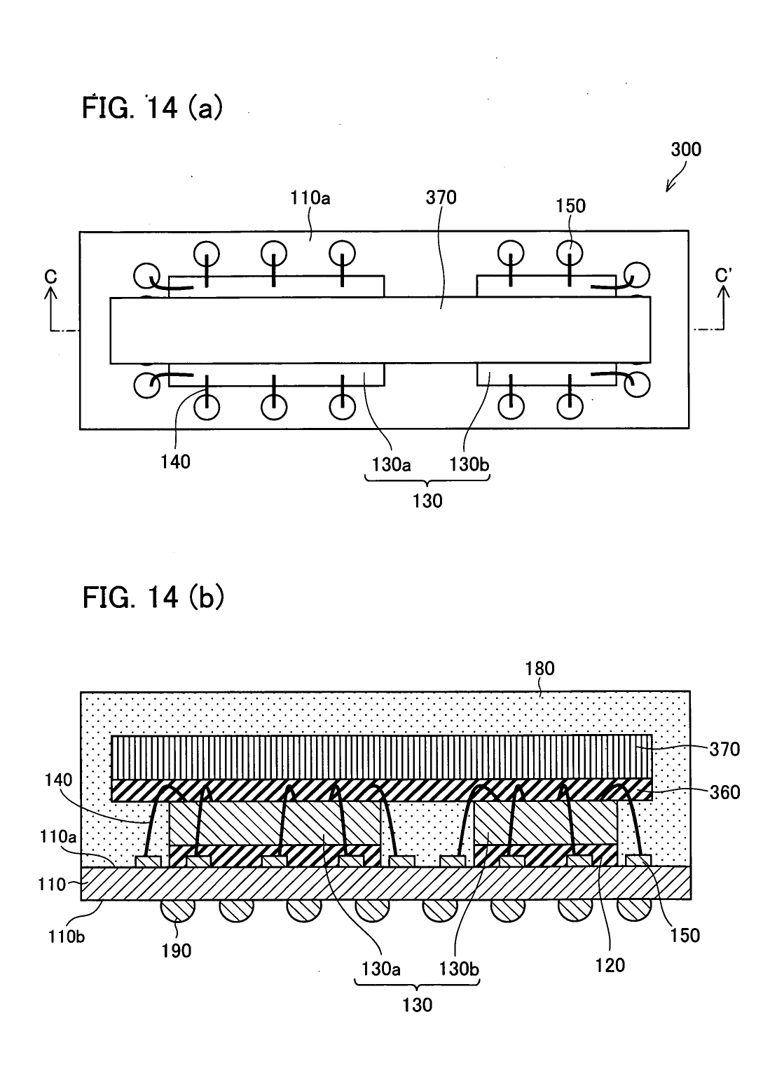

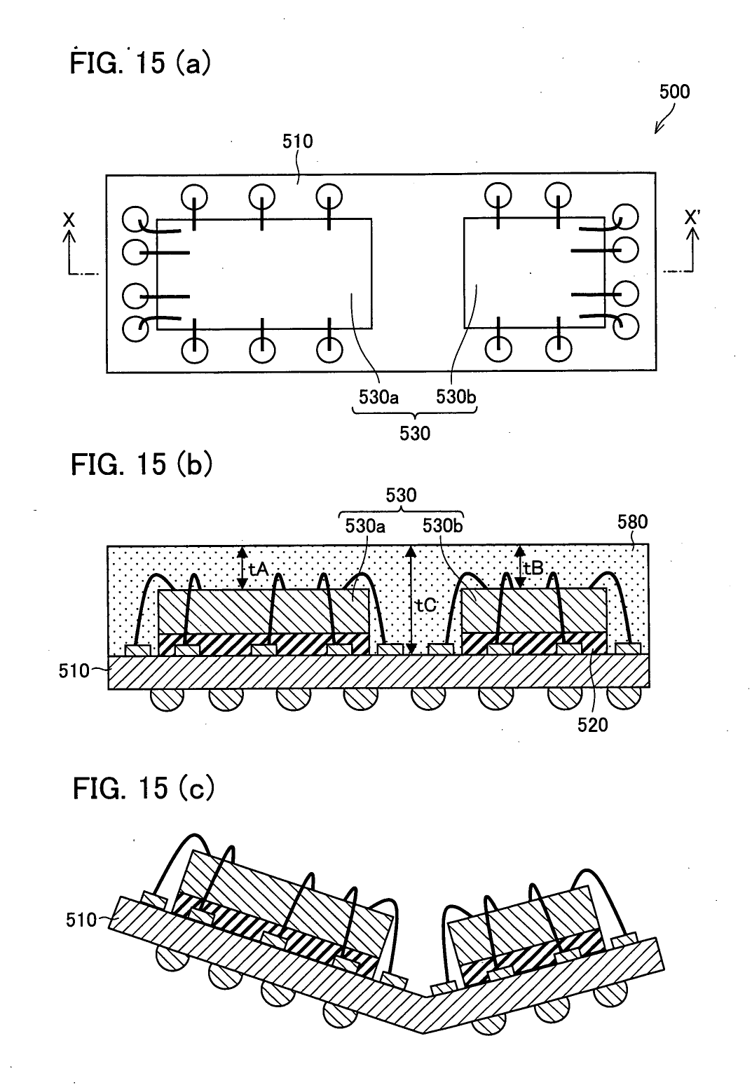

The following explains a still another embodiment of the present invention with reference to FIGS. 14(a) and 14(b). The arrangement other than explained below is the same as the arrangement of the first embodiment. For convenience of explanation, members given the same reference numerals as the members explained in the first embodiment respectively have identical functions and the explanations thereof are omitted.

FIG. 14(a) is a plan view illustrating a semiconductor device 300 of the present embodiment. FIG. 14(b) is a cross sectional view taken along C-C′ of FIG. 14(a). In FIG. 14(a), a sealing resin 180 is omitted for assisting the understanding of the drawing.

In the semiconductor device 300 of the present embodiment, a second adhesive layer 360 and a hard member 370 are provided. The second adhesive layer 360 and the hard member layer 370 respectively have shapes of the second adhesive layer 160 and the hard member 170 of a semiconductor device 100 in the first embodiment which second adhesive layer 160 and the hard member 170 are extended in a longitudinal direction of a first surface 110a of a substrate 110 and have a reduced width on a plane facing the first substrate 110a in a direction perpendicular to the longitudinal direction on the plane parallel to the first plane 110a. Thereby, a second adhesive layer 360 and a hard member 370 are formed. The second adhesive layer 360 and the hard member 370 are provided to bridge semiconductor chips 130a and 130b and has an overhung structure.

An area of a surface of the hard member 370 which surface faces the first surface 110a is formed to be larger than a total area of surfaces of the semiconductor chips 130a and 130b which surfaces face the hard member 370.

It is preferable that the hard member 370 is made of a material that has a thermal expansion coefficient of one to two times thermal expansion coefficients of the semiconductor chips 130a and 130b.

This arrangement makes deformation, such as warping, of the semiconductor device 300 of the present embodiment hard to occur. Therefore, reliability of the operation of the semiconductor device 300 can be maintained against a sufficient number of times of temperature cycles.

Moreover, because the semiconductor device 300 of the present embodiment includes the hard member 370 above, the strength of the semiconductor device 300 can be improved compared with the strength of the semiconductor device with only a substrate, a sealing resin, and the like. This makes it possible to reduce a thickness of a member whose strength is supported with the substrate, the sealing resin, and the like. Therefore, it becomes possible to produce a thin semiconductor device that prevents warping.

In addition, the sealing resin 180 of the semiconductor device may be partially or entirely removed as illustrated in FIGS. 7 through 9.

The present invention is not limited to the description of the embodiments above, but may be altered by a skilled person within the scope of the claims. An embodiment based on a proper combination of technical means disclosed in different embodiments is encompassed in the technical scope of the present invention.

Further, more semiconductor chips and hard members may be stacked to form additional upper layers with a combination of the methods of stacking the layers, although the explanation above dealt with an arrangement in which the semiconductor chips and the hard member are stacked to form up to three layers.

According to the present invention, because the semiconductor device includes a hard member, it becomes possible to prevent an operation to deform the semiconductor device when heat load is applied to the semiconductor device. Therefore, the present invention is applicable in formation of a package of integrated circuits, for example, a multi-chip module semiconductor device in which a plurality of semiconductor chips are mounted on one plane and assembled in one IC package, or a stacked multi-chip module semiconductor device in which a plurality of semiconductor chips are stacked three-dimensionally.

As mentioned above, a semiconductor device of the present invention including a plurality of semiconductor elements on a substrate, the semiconductor device includes: a plurality of semiconductor elements being provided two-dimensionally on a first surface of the substrate via an adhesive layer; and a hard member being provided via another adhesive layer on surfaces of the plurality of semiconductor elements provided on the first surface, the surfaces being on an opposite side with respect to other surfaces of the plurality semiconductor elements provided on the first surface which other surfaces facing the first surface.

According to the arrangement, the hard member is provided on the plurality of semiconductor elements. In other words, the hard member is provided so as to bridge the plurality of semiconductor elements provided in the semiconductor device of the present invention. Thus, the hard member functions as a support. Therefore, deformation of the semiconductor device of the present invention is hard to occur.

A semiconductor device of the present invention includes: a hard member provided on a first surface of the substrate via an adhesive layer; and a plurality of semiconductor elements provided two-dimensionally via another adhesive layer on a surface of the hard member which surface is on an opposite side to another surface of the hard member which another surface faces the first surface.

According to the arrangement, the hard member is provided on the substrate of the semiconductor device of the present invention via the adhesive layer, and the plurality of semiconductor elements are provided on the hard member via the another adhesive layer. In other words, the hard member is provided to strengthen the substrate. Therefore, deformation of the semiconductor device of the present invention is hard to occur.

Moreover, the semiconductor device of the present invention may have an arrangement in which another hard member on surfaces of the plurality of semiconductor elements via still another adhesive layer which surfaces are on opposite sides of other surfaces of the plurality of semiconductor elements which other surfaces face the first surface.

According to the arrangement, because the hard members are provided above and below the plurality of semiconductor elements, respectively, it becomes possible to realize a semiconductor device having improved rigidity. Therefore, deformation, such as warping, of the semiconductor device is hard to occur, even when heat load from a sufficient number of times of temperature cycles is applied.

The semiconductor device of the present invention may include a plurality of semiconductor elements further provided on one plane via still another adhesive layer on another surface of the hard member, the another surface of the hard member being on an opposite side of the surface facing the first surface.

According to the arrangement, the plurality of semiconductor elements are combined three-dimensionally. In other words, the plurality of semiconductor elements can be mounted at a high density. Moreover, deformation, such as warping, of the semiconductor device is hard to occur, even when heat load from a sufficient number of times of temperature cycles is applied.

The arrangement of the semiconductor device of the present invention may be such that an area of the surface of the hard member which surface faces the first surface is larger than a total area of the surfaces of the plurality of semiconductor elements being provided closer to the first surface than the another adhesive layer provided on the surface of the hard member, the surface of the hard member facing the first surface, the surfaces of the plurality of semiconductor elements facing the first surface.

According to the arrangement, because the area of the surface of the hard member is large, warping and deformation of the semiconductor device becomes hard to occur. In addition, heat dissipation of the semiconductor device improves. In other words, reliability of the operation of the semiconductor device can be maintained against a sufficient number of times of temperature cycles.

The arrangement of the semiconductor device of the present invention may be such that a value of a thermal expansion coefficient of the hard member is one to two times a value of a thermal expansion coefficient of the plurality of semiconductor elements.

In a case where the hard member is made of a material that has the thermal expansion coefficient of more than twice the thermal expansion coefficient of the semiconductor device, the hard member extends or shrinks more significantly than the semiconductor elements when heat load is applied. This may cause a crack inside the semiconductor device or destroy the semiconductor element. Therefore, it is preferable that the thermal expansion coefficient of the hard member is less than two times the thermal expansion coefficient of the semiconductor element.

Moreover, in a case where the hard member is provided between the substrate and the plurality of semiconductor elements, the thermal expansion coefficient of the hard member is lower than that of the substrate but higher than that of the semiconductor element. Therefore, in a case where heat load is applied to the semiconductor device of the present invention, the hard member reduces extension or shrinkage due to heat in the substrate. This reduces the difference between the substrate and the semiconductor device in regard to extension or shrinkage due to heat. Therefore, it becomes possible to suppress warping of the semiconductor device.

In the semiconductor device of the present invention, the hard member may be made of silicon or ceramics.

According to the arrangement, a value of the thermal expansion coefficient of the hard member may be one to two times a value of a thermal expansion coefficient of a typical semiconductor element.

Moreover, the hard member may be made of a semiconductor element.

According to the arrangement, it becomes possible to provide the semiconductor element in a position where the hard member is to be provided. Accordingly, a plurality of semiconductor elements can be mounted at a high density. Moreover, deformation, such as warping, of the semiconductor device becomes hard to occur due to a sufficient number of times of temperature cycles.

In the semiconductor device of the present invention, the plurality of semiconductor elements provided on the first surface, the hard member, and the adhesive layers are sealed with resin.

According to the arrangement, it becomes possible to prevent mechanical deformation due to resin in the semiconductor device.

The semiconductor device of the present invention is further provided with another hard member. Therefore, it becomes possible to suppress warping of the semiconductor device caused by difference between the resin and the semiconductor elements in regard to extension or shrinkage due to heat.

The semiconductor device of the present invention may have an arrangement in which, simultaneously, the plurality of semiconductor elements provided on the first surface, the hard member, and the adhesive layers are sealed with resin, and an opening is formed in the resin on a part of a surface of the semiconductor element or the hard member provided in a position farthest from the first surface which surface faces in a direction away from the first surface, thereby exposing the part of the surface from the resin.

According to the arrangement, because the sealing resin is not provided on the surface of the hard member provided farthest with respect to the first surface, it becomes possible to improve heat dissipation of the semiconductor device.

In particular, in a case where the member provided in a position farthest to the first member is a hard member made of a semiconductor element, a part of a surface of this semiconductor element is exposed outside. It becomes possible to produce a semiconductor sensor that can suppress warping with the use of a light receiving element, a sensor chip, or the like, for example, a CCD or CMOS image sensor, as this semiconductor element. Moreover, with the use of a light-emitting element such as an LED, it becomes possible to produce a light-emitting device that can suppress warping.

The semiconductor device of the present invention may have an arrangement in which a structure formed by stacking the plurality of semiconductor elements provided on the first surface, the hard member, and the adhesive layers is exposed outside.

According to the arrangement, because the sealing resin is not provided, heat dissipation of the semiconductor device improves.

The semiconductor device of the present invention may have an arrangement in which electrical connection is made between the plurality of semiconductor elements and external connection electrodes formed on a second surface on an opposite side of the first surface, respectively, the first surface and the second surface being surfaces of the substrate, the electrical connection being made by: electrical connection with the use of fine metal wires between wiring electrodes provided on the first surface and the plurality of semiconductor elements; and electrical connection between the wiring electrodes and the external connection electrodes; and the another adhesive layer is provided so as to cover at least a part of the fine metal wires.

According to the arrangement, particularly in a case where resin is provided to the first surface, deformation of the fine metal wires can be suppressed. Therefore, it becomes possible to employ thinner fine metal wires. In other words, material cost can be reduced.

The semiconductor device of the present invention may have an arrangement in which electrical connection is made between the plurality of semiconductor elements and external connection electrodes formed on a second surface on a side opposite of the first surface, respectively, the first surface and the second surface being surfaces of the substrate, the electrical connection being made by: electrical connection between wiring electrodes provided on the first surface and the plurality of semiconductor elements via through-hole electrodes that the plurality of semiconductor elements and the hard member include, the through-hole electrodes penetrating the plurality of the semiconductor elements and the hard member between surfaces facing the first surface and surfaces on opposite sides of the first surface, respectively; and electrical connection between the wiring electrodes and the external connection electrodes.

According to the arrangement, the electrical connection is realized by the through-hole electrodes. Therefore, it becomes possible to produce a semiconductor device having a smaller package size.

The semiconductor device of the present invention may have an arrangement in which electrical connection are made between the plurality of semiconductor elements and external connection electrodes formed on a second surface on an opposite side of the first surface, respectively, the first surface and the second surface being surfaces of the substrate, the electrical connection being made by: electrical connection with the use of fine metal wires between crimp bump electrodes provided by crimping on wiring electrodes on the first surface and bump electrodes provided to the plurality of semiconductor elements; and electrical connection between the wiring electrodes and the external connection electrodes.

According to the arrangement, in the electrical connection with the fine metal wires, it becomes possible to prevent a contact between the semiconductor element and the fine metal wires. Moreover, it also becomes possible to make an angle between the first surface and the fine metal wires become closer to a right angle. Accordingly, it becomes possible to further reduce a distance between the wiring electrodes provided on the first surface and the bump electrodes provided on the semiconductor elements. This makes it possible to provide a semiconductor device of a smaller package size.

A method of producing a semiconductor device includes steps of: forming an adhesive layer on a first surface of the substrate; providing a plurality of semiconductor elements on the adhesive layer; providing another adhesive layer on surfaces of the plurality of semiconductor elements which surfaces are on opposite sides to other surfaces of the plurality of semiconductor elements which other surfaces faces the first substrate; and providing a hard member on the another adhesive layer.

In other words, the semiconductor device is produced by sandwiching the plurality of semiconductor elements between the first surface of the substrate and the hard member.

The hard member is provided to bridge the plurality of semiconductor elements and provided between the plurality of semiconductor elements so as to function as a support. Therefore, deformation of the semiconductor device of the present invention becomes hard to occur.

A method of producing a semiconductor device includes steps of: forming an adhesive layer on a first surface of the substrate; providing a hard member on the adhesive layer; providing another adhesive layer on a surface of the hard member which surface is on an opposite side to a surface of the hard member which surface faces the first substrate; and providing the plurality of semiconductor elements on the another adhesive layer.

In other words, the hard member is provided on the substrate of the semiconductor device of the present invention via the adhesive layer, and the plurality of semiconductor elements are further provided on the hard member via the another adhesive layer.

Therefore, because the hard member is provided so as to strengthen the substrate, deformation of the semiconductor device of the present invention is hard to occur.

In addition, as explained above, deformation of the semiconductor device is hard to occur, it becomes possible to reduce a thickness of a strengthening member used to prevent deformation of the semiconductor device. Therefore, it becomes possible to realize a thin semiconductor device that can prevent warping.

On this account, the present invention is effective in providing a thin semiconductor device that prevents warping of the semiconductor device including a plurality of semiconductor elements.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device including a plurality of semiconductor elements on a substrate, the semiconductor device comprising:
a plurality of semiconductor elements being provided two-dimensionally on a first surface of the substrate via an adhesive layer; and
a hard member being provided via another adhesive layer on surfaces of the plurality of semiconductor elements provided on the first surface, the surfaces being on an opposite side with respect to other surfaces of the plurality semiconductor elements provided on the first surface which other surfaces facing the first surface.

2. The semiconductor device as set forth in claim 1, further comprising:
a plurality of semiconductor elements further provided on one plane via still another adhesive layer on another surface of the hard member, the another surface of the hard member being on an opposite side of the surface facing the first surface.

3. The semiconductor device as set forth in claim 1, wherein:
an area of the surface of the hard member which surface faces the first surface is larger than a total area of the surfaces of the plurality of semiconductor elements being provided closer to the first surface than the another adhesive layer provided on the surface of the hard member, the surface of the hard member facing the first surface, the surfaces of the plurality of semiconductor elements facing the first surface.

4. The semiconductor device as set forth in claim 1, wherein:
a value of a thermal expansion coefficient of the hard member is one to two times a value of a thermal expansion coefficient of the plurality of semiconductor elements.

5. The semiconductor device as set forth in claim 1, wherein:
the hard member is made of silicon, ceramics, or a semiconductor element.

6. The semiconductor device as set forth in claim 1, wherein:
the plurality of semiconductor elements provided on the first surface, the hard member, and the adhesive layers are sealed with resin.

7. The semiconductor device as set forth in claim 1, wherein:
simultaneously, the plurality of semiconductor elements provided on the first surface, the hard member, and the adhesive layers are sealed with resin, and an opening is formed in the resin on a part of a surface of the semiconductor element or the hard member provided in a position farthest from the first surface which surface faces in a direction away from the first surface, thereby exposing the part of the surface from the resin.

8. The semiconductor device as set forth in claim 1, wherein:
a structure formed by stacking the plurality of semiconductor elements provided on the first surface, the hard member, and the adhesive layers is exposed outside.

9. The semiconductor device as set forth in claim 1, wherein:
electrical connection is made between the plurality of semiconductor elements and external connection electrodes formed on a second surface on an opposite side of the first surface, respectively, the first surface and the second surface being surfaces of the substrate, the electrical connection being made by:
electrical connection with the use of fine metal wires between wiring electrodes provided on the first surface and the plurality of semiconductor elements; and
electrical connection between the wiring electrodes and the external connection electrodes; and
the another adhesive layer is provided so as to cover at least a part of the fine metal wires.

10. The semiconductor device as set forth in claim 1, wherein:
electrical connection is made between the plurality of semiconductor elements and external connection electrodes formed on a second surface on a side opposite of the first surface, respectively, the first surface and the second surface being surfaces of the substrate, the electrical connection being made by:
electrical connection between wiring electrodes provided on the first surface and the plurality of semiconductor elements via through-hole electrodes that the plurality of semiconductor elements and the hard member include, the through-hole electrodes penetrating the plurality of the semiconductor elements and the hard member between surfaces facing the first surface and surfaces on opposite sides of the first surface, respectively; and
electrical connection between the wiring electrodes and the external connection electrodes.

11. The semiconductor device as set forth in claim 1, wherein:
electrical connection are made between the plurality of semiconductor elements and external connection electrodes formed on a second surface on an opposite side of the first surface, respectively, the first surface and the second surface being surfaces of the substrate, the electrical connection being made by:
electrical connection with the use of fine metal wires between crimp bump electrodes provided by crimping on wiring electrodes on the first surface and bump electrodes provided to the plurality of semiconductor elements; and
electrical connection between the wiring electrodes and the external connection electrodes.

12. A semiconductor device including a plurality of semiconductor elements on a substrate, the semiconductor device comprising:
a hard member provided on a first surface of the substrate via an adhesive layer; and
a plurality of semiconductor elements provided two-dimensionally via another adhesive layer on a surface of the hard member which surface is on an opposite side to another surface of the hard member which another surface faces the first surface.

13. The semiconductor device as set forth in claim 12, further comprising:
another hard member on surfaces of the plurality of semiconductor elements via still another adhesive layer which surfaces are on opposite sides of other surfaces of the plurality of semiconductor elements which other surfaces face the first surface.

14. The semiconductor device as set forth in claim 12, wherein:
an area of the surface of the hard member which surface faces the first surface is larger than a total area of the surfaces of the plurality of semiconductor elements being provided closer to the first surface than the another adhesive layer provided on the surface of the hard member, the surface of the hard member facing the first surface, the surfaces of the plurality of semiconductor elements facing the first surface.

15. The semiconductor device as set forth in claim 12, wherein:
a value of a thermal expansion coefficient of the hard member is one to two times a value of a thermal expansion coefficient of the plurality of semiconductor elements.

16. The semiconductor device as set forth in claim 12, wherein:
the hard member is made of silicon, ceramics, or a semiconductor element.

17. The semiconductor device as set forth in claim 12, wherein:
the plurality of semiconductor elements provided on the first surface, the hard member, and the adhesive layers are sealed with resin.

18. The semiconductor device as set forth in claim 12, wherein:
simultaneously, the plurality of semiconductor elements provided on the first surface, the hard member, and the adhesive layers are sealed with resin, and an opening is formed in the resin on a part of a surface of the semiconductor element or the hard member provided in a position farthest from the first surface which surface faces in a direction away from the first surface, thereby exposing the part of the surface from the resin.

19. The semiconductor device as set forth in claim 12, wherein:
a structure formed by stacking the plurality of semiconductor elements provided on the first surface, the hard member, and the adhesive layers is exposed outside.

20. The semiconductor device as set forth in claim 12, wherein:
electrical connection is made between the plurality of semiconductor elements and external connection electrodes formed on a second surface on an opposite side of the first surface, respectively, the first surface and the second surface being surfaces of the substrate, the electrical connection being made by:
electrical connection with the use of fine metal wires between wiring electrodes provided on the first surface and the plurality of semiconductor elements; and
electrical connection between the wiring electrodes and the external connection electrodes; and
the another adhesive layer is provided so as to cover at least a part of the fine metal wires.

21. The semiconductor device as set forth in claim 12, wherein:
electrical connection is made between the plurality of semiconductor elements and external connection electrodes formed on a second surface on a side opposite of the first surface, respectively, the first surface and the second surface being surfaces of the substrate, the electrical connection being made by:
electrical connection between wiring electrodes provided on the first surface and the plurality of semiconductor elements via through-hole electrodes that the plurality of semiconductor elements and the hard member include, the through-hole electrodes penetrating the plurality of the semiconductor elements and the hard member between surfaces facing the first surface and surfaces on opposite sides of the first surface, respectively; and
electrical connection between the wiring electrodes and the external connection electrodes.

22. The semiconductor device as set forth in claim 12, wherein:
electrical connection are made between the plurality of semiconductor elements and external connection electrodes formed on a second surface on an opposite side of the first surface, respectively, the first surface and the second surface being surfaces of the substrate, the electrical connection being made by:
electrical connection with the use of fine metal wires between crimp bump electrodes provided by crimping on wiring electrodes on the first surface and bump electrodes provided to the plurality of semiconductor elements; and
electrical connection between the wiring electrodes and the external connection electrodes.

23. A method of producing a semiconductor device including a plurality of semiconductor elements on a substrate, comprising steps of:
forming an adhesive layer on a first surface of the substrate;
providing a plurality of semiconductor elements on the adhesive layer;
providing another adhesive layer on surfaces of the plurality of semiconductor elements which surfaces are on opposite sides to other surfaces of the plurality of semiconductor elements which other surfaces faces the first substrate; and
providing a hard member on the another adhesive layer.

24. A method of producing a semiconductor device including a plurality of semiconductor elements on a substrate, comprising steps of:
forming an adhesive layer on a first surface of the substrate;
providing a hard member on the adhesive layer;
providing another adhesive layer on a surface of the hard member which surface is on an opposite side to a surface of the hard member which surface faces the first substrate; and
providing the plurality of semiconductor elements on the another adhesive layer.
